(19) United States
(12) Patent Application Publication
(10) Pub. No.: US 2025/0244500 A1
(43) Pub. Date: Jul. 31, 2025

(54) MODELLING OVERLAPPING HYDRAULIC FRACTURES

(71) Applicant: SAUDI ARABIAN OIL COMPANY, Dhahran (SA)

(72) Inventors: Zhen Chen, Dhahran (SA); Ali Dogru, Dhahran (SA); Tareq Shaalan, Dhahran (SA)

(73) Assignee: SAUDI ARABIAN OIL COMPANY, Dhahran (SA)

(21) Appl. No.: 18/423,165

(22) Filed: Jan. 25, 2024

(51) Int. Cl. G01V 20/00; E21B 43/26; G06F 30/28

(52) U.S. Cl. CPC G01V 20/00; G06F 30/28; E21B 43/26; E21B 2200/20

(57) ABSTRACT

A method includes modeling initial production and production rates of a modeled first well using a first set of modeled fractures prior to initialization of production on a modeled second well; modeling initial production and production rates of the modeled second well, using a second set of modeled fractures and a set of modeled overlapping fractures, after the modeled first well has been producing for a period of time; analyzing an effect on the production rates of the modeled first well, wherein the effect is a change in production rates due to the set of modeled overlapping fractures and the initial production on the modeled second well; and minimizing the effect on the production rates of the modeled first well by updating locations of the first set of modeled fractures and the second set of modeled fractures to optimize the set of modeled overlapping fractures.

### BACKGROUND

Hydrocarbons are located in porous rock formations beneath the Earth's surface. Wells are drilled into these formations to access and produce the hydrocarbons. Tight reservoirs are a category of hydrocarbon reservoirs that have low permeability. It is difficult to efficiently produce hydrocarbons from tight reservoirs because low permeability prevents hydrocarbons from flowing through the pores of the formation into the well. As such, horizontal wells are drilled into these reservoirs and artificial fractures are created from these wells to artificially increase the permeability of the reservoir and create pathways for hydrocarbons to flow into the well. Because permeability is often so low in these formations, wells are drilled and fractured close to one another to ensure an optimal volume of the reservoir is stimulated. When wells are located close to one another, neighboring fractures may overlap. Overlapping fractures add complexities to conventional reservoir and production modeling techniques.

### SUMMARY

This summary is provided to introduce a selection of concepts that are further described below in the detailed description. This summary is not intended to identify key or essential features of the claimed subject matter, nor is it intended to be used as an aid in limiting the scope of the claimed subject matter.

This disclosure presents, in accordance with one or more embodiments methods and systems for fracturing a first well and a second well in a sub-surface reservoir. The method includes modeling the first well and the second well in a reservoir model representing the sub-surface reservoir to create a modeled first well and a modeled second well; modeling a first set of planned fractures extending from the first well and a second set of planned fractures extending from the second well in the reservoir model to create a first set of modeled fractures and a second set of modeled fractures; and modeling a set of planned overlapping fractures to create a set of modeled overlapping fractures, wherein the set of modeled overlapping fractures includes at least one modeled fracture from the first set of modeled fractures that overlaps with a corresponding modeled fracture in the second set of modeled fractures. The method further includes modeling initial production and production rates of the modeled first well using the first set of modeled fractures prior to initialization of production on the modeled second well; modeling initial production and production rates of the modeled second well, using the second set of modeled fractures and the set of modeled overlapping fractures, after the modeled first well has been producing for a period of time; and analyzing an effect on the production rates of the modeled first well, wherein the effect is a change in production rates due to the set of modeled overlapping fractures and the initial production on the modeled second well. The method finally includes minimizing the effect on the production rates of the modeled first well by updating locations of the first set of modeled fractures and the second set of modeled fractures to optimize the set of modeled overlapping fractures.

The system includes a fracturing system comprising a pump truck configured to pump a frac fluid into the first well to create a first set of fractures extending from the first well into the sub-surface reservoir and pump the frac fluid into the second well to create a second set of fractures extending from the second well into the sub-surface reservoir. The system also includes a computer system coupled to the fracturing system and configured to perform functionalities related to modeling the first well and the second well in a reservoir model representing the sub-surface reservoir to create a modeled first well and a modeled second well; modeling a first set of planned fractures extending from the first well and a second set of planned fractures extending from the second well in the reservoir model to create a first set of modeled fractures and a second set of modeled fractures; and modeling a set of planned overlapping fractures to create a set of modeled overlapping fractures, wherein the set of modeled overlapping fractures includes at least one modeled fracture from the first set of modeled fractures that overlaps with a corresponding modeled fracture in the second set of modeled fractures. The computer system is also configured to perform functionalities related to modeling initial production and production rates of the modeled first well using the first set of modeled fractures prior to initialization of production on the modeled second well; modeling initial production and production rates of the modeled second well, using the second set of modeled fractures and the set of modeled overlapping fractures, after the modeled first well has been producing for a period of time; analyzing an effect on the production rates of the modeled first well, wherein the effect is a change in production rates due to the set of modeled overlapping fractures and the initial production on the modeled second well; and minimizing the effect on the production rates of the modeled first well by updating locations of the first set of modeled fractures and the second set of modeled fractures to optimize the set of modeled overlapping fractures.

Other aspects and advantages of the claimed subject matter will be apparent from the following description and the appended claims.

### BRIEF DESCRIPTION OF DRAWINGS

Specific embodiments of the disclosed technology will now be described in detail with reference to the accompanying figures. Like elements in the various figures are denoted by like reference numerals for consistency. The sizes and relative positions of elements in the drawings are not necessarily drawn to scale. For example, the shapes of various elements and angles are not necessarily drawn to scale, and some of these elements may be arbitrarily enlarged and positioned to improve drawing legibility. Further, the particular shapes of the elements as drawn are not necessarily intended to convey any information regarding the actual shape of the particular elements and have been solely selected for ease of recognition in the drawing.

FIG. 1 shows a flowchart in accordance with one or more embodiments.

FIGS. 2A-2C show the first well and the second well in accordance with one or more embodiments.

FIGS. 3A-3C show the modeled first well and the modeled second well in the reservoir model in accordance with one or more embodiments.

FIG. 4 shows a plot of production rate over time for the modeled first well in accordance with one or more embodiments.

FIG. 5 shows a hydraulic fracturing site undergoing a hydraulic fracturing operation in accordance with one or more embodiments.

FIG. 6 shows a computer system in accordance with one or more embodiments.

FIG. 7a shows one level of grid refinement in accordance with one or more embodiments.

FIG. 7b shows three levels of refinement in accordance with one or more embodiments.

### DETAILED DESCRIPTION

In the following detailed description of embodiments of the disclosure, numerous specific details are set forth in order to provide a more thorough understanding of the disclosure. However, it will be apparent to one of ordinary skill in the art that the disclosure may be practiced without these specific details. In other instances, well-known features have not been described in detail to avoid unnecessarily complicating the description.

Throughout the application, ordinal numbers (e.g., first, second, third, etc.) may be used as an adjective for an element (i.e., any noun in the application). The use of ordinal numbers is not to imply or create any particular ordering of the elements nor to limit any element to being only a single element unless expressly disclosed, such as using the terms “before”, “after”, “single”, and other such terminology. Rather, the use of ordinal numbers is to distinguish between the elements. By way of an example, a first element is distinct from a second element, and the first element may encompass more than one element and succeed (or precede) the second element in an ordering of elements.

Overlapping fractures between neighboring wells affect the production of each of these wells. Herein the term overlapping fractures may encompass fractures between two wells that literally combine with one another to create a single fracture in communication with both wells. The term overlapping fractures may also encompass fractures that are close enough to one another that their drainage areas overlap. No matter which of these two definitions are used to define “overlapping fractures,” it is clear that overlapping fractures cause the production of one neighboring well to affect the production of the other neighboring well.

Conventional modeling techniques fail to sufficiently model overlapping fractures because they normally truncate or remove the overlapping fractures, which loses accuracy in modeling. The present disclosure generates a grid for all of the overlapping fractures. Particularly a smoothing technique is used in case overlapped fractures collide into each other, and the smoothing technique is used to fit many hydraulic fracture grids into a base grid. More importantly, conventional modeling does not consider the dynamical change of permeability in hydraulic fractures. Wells begin production at different times. Thus, to model the influence of overlapping fractures, modeling the dynamic change of time-dependent permeability in hydraulic fractures is essential. As such, the present disclosure outlines systems and methods that model overlapping fractures while taking into account both space and time dimensions. Furthermore, the disclosed systems and methods model the overlapping fractures using a combination of dynamic permeability models and special gridding techniques.

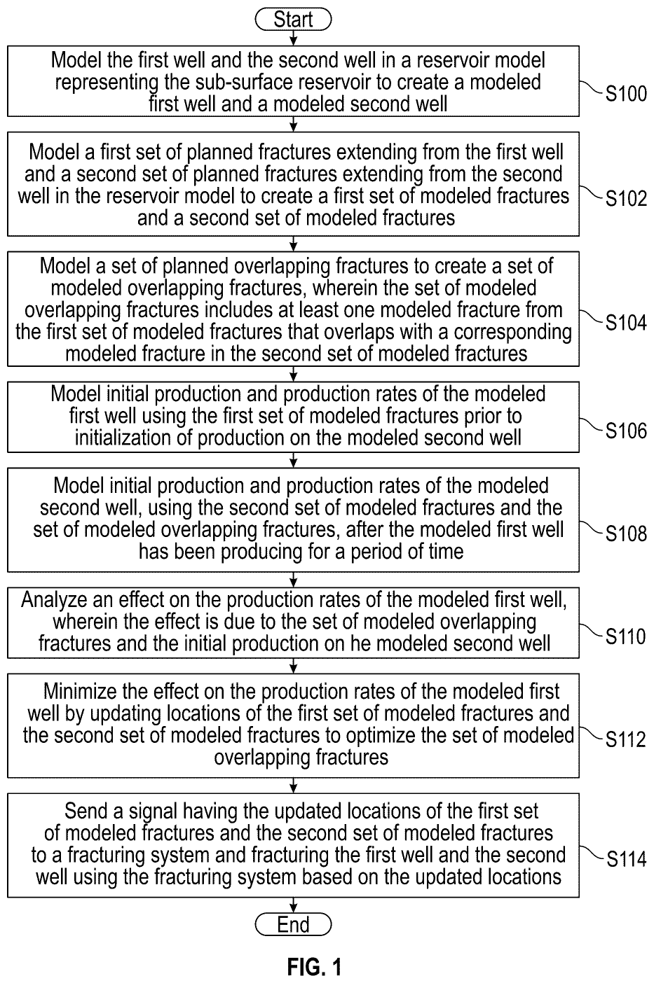

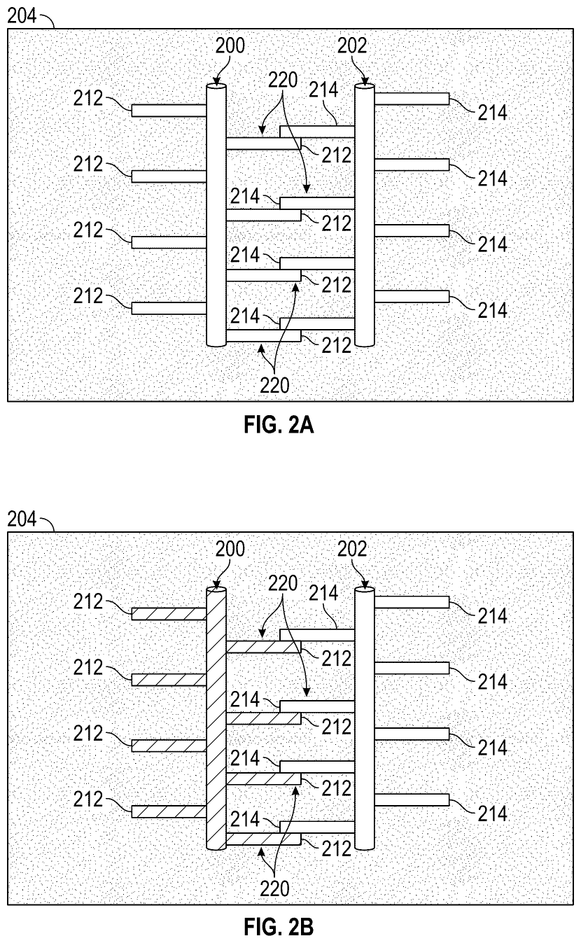

FIG. 1 shows a flowchart in accordance with one or more embodiments. The flowchart outlines a method for fracturing a first well (200) and a second well (202) in a sub-surface reservoir (204). FIGS. 2A-6 are used to outline various embodiments of the steps shown in FIG. 1 While the various blocks in FIG. 1 are presented and described sequentially, one of ordinary skill in the art will appreciate that some or all of the blocks may be executed in different orders, may be combined or omitted, and some or all of the blocks may be executed in parallel. Furthermore, the blocks may be performed actively or passively.

In S100, the first well (200) and the second well (202) are modeled in a reservoir model (206) representing the sub-surface reservoir (204) to create a modeled first well (208) and a modeled second well (210). A person skilled in the art will appreciate that, while the present disclosure only shows examples of modeling and fracturing two wells, any number of wells having at least one overlapping fracture may be used without departing from the scope of the disclosure herein.

FIGS. 2A-2C show the first well (200) and the second well (202) in accordance with one or more embodiments. The first well (200) and the second well (202) may be planned wellbores or actual wells that have already been drilled into the sub-surface reservoir (204) without departing from the scope of the disclosure herein.

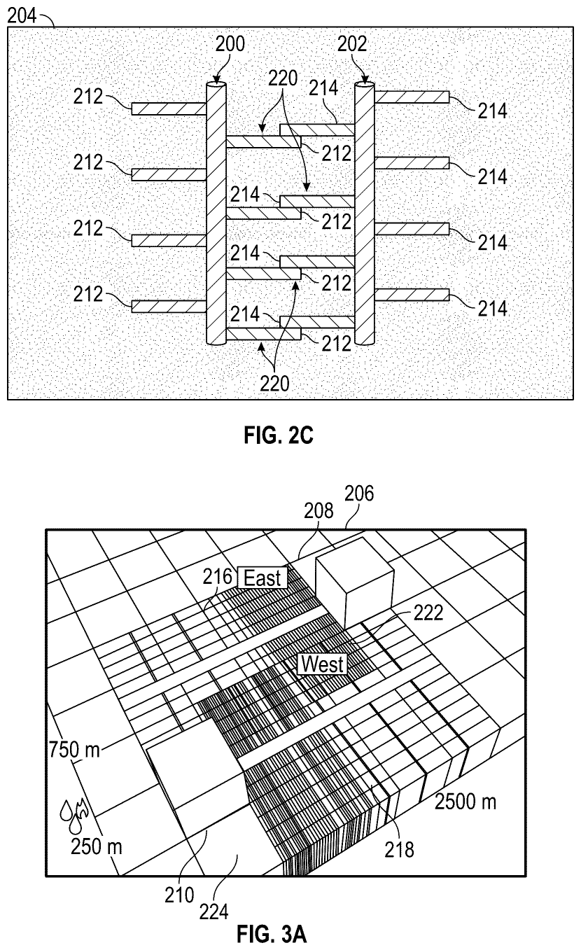

FIGS. 3A-3C show the modeled first well (208) and the modeled second well (210) in the reservoir model (206). The modeled first well (208) and the modeled second well (210) digitally represent the planned or drilled first well (200) and second well (202) outlined in FIGS. 2A-2C. That is, the modeled first well (208) and the modeled second well (210) have the same location, dimensions, and wellbore trajectory in the reservoir model (206) as the location, dimensions, and wellbore trajectory of the first well (200) and the second well (202) in the sub-surface reservoir (204).

In accordance with one or more embodiments, the reservoir model (206) is made of a plurality of grid cells (224) each representing various data points about the sub-surface reservoir (204). Specifically, the reservoir model (206) is created by upscaling a geological model representing geological properties of the sub-surface reservoir (204). The geological properties include all data about the sub-surface reservoir (204) that are known, interpolated, and/or calculated from seismic data, well logs, historical wells, etc.

In accordance with one or more embodiments, the geological model is upscaled to create the reservoir model (206) by combing the geological model with data from fluid models, relative permeability models, and equilibrium models. In accordance with one or more embodiments, the data includes relative permeability, capillary pressure, etc. The permeability models include data that represents the permeability of the sub-surface reservoir (204). The fluid models include data that represents the fluid (and locations of the fluid) in the sub-surface reservoir (204). The data in the fluid and permeability models may have also been gathered from seismic data, well logs, historical wells, etc.

Turning back to FIG. 1, in S102, a first set of planned fractures (212) extending from the first well (200) and a second set of planned fractures (214) extending from the second well (202) are modeled in the reservoir model (206) to create a first set of modeled fractures (216) and a second set of modeled fractures (218). The first set of planned fractures (212) and the second set of planned fractures (214) are shown in FIGS. 2A-2C. The first set of modeled fractures (216) and the second set of modeled fractures (218) are shown in FIGS. 3A-3C.

FIGS. 2A-2C show the first set of planned fractures (212) extending from the first well (200) in the sub-surface reservoir (204). In accordance with one or more embodiments, the first set of planned fractures (212) include eight fractures extending from the first well (200) at equal intervals. FIGS. 2A-2C show the second set of planned fractures (214) extending from the second well (202) in the sub-surface reservoir (204). In accordance with one or more embodiments, the second set of planned fractures (214) include eight fractures extending from the second well (202) at equal intervals. A person skilled in the art will appreciate that while FIGS. 2A-2C show specific fracture designs, any configuration (number, type, orientation, length, etc.) of fractures may be planned without departing from the scope of the disclosure herein.

FIGS. 3A-3C show the first set of modeled fractures (216) extending from the modeled first well (208) and the second set of modeled fractures (218) extending from the modeled second well (210) in the reservoir model (206). In accordance with one or more embodiments, the first set of modeled fractures (216) and the second set of modeled fractures (218) are modeled using a geo-mechanical stress model of the sub-surface reservoir (204), the wellbore trajectory (actual or planned) of the first well (200) and the second well (202), and the planned perforation (or fracture initiation) scheme of the first well (200) and the second well (202).

In accordance with one or more embodiments, the geo-mechanical stress model is created using the state of stress, the pore pressures, and the rock properties of the sub-surface reservoir (204). The state of stress, the pore pressures, and the rock properties of the sub-surface reservoir (204) may be known, interpolated, and/or calculated from seismic data, well logs, historical wells, etc.

Once compiled into the geo-mechanical stress model, the first set of modeled fractures (216) and the second set of modeled fractures (218) may be created by modeling the initiation of the first set of planned fractures (212) and the second set of planned fractures (214). Specifically, the geo-mechanical stress model uses the location and wellbore trajectory of the first well (200) and the second well (202) in the sub-surface reservoir (204), the planned perforation (or fracture initiation) scheme, and the design of the frac operation (e.g., pump pressures, time, etc.) to show how the fractures should propagate in the sub-surface reservoir (204). The propagation of the fractures may be used in conjunction with reservoir data to determine each fracture's corresponding drainage area (also known as stimulated reservoir volume). In accordance with one or more embodiments, the first set of modeled fractures (216) and the second set of modeled fractures (218) represent these potential propagations and/or drainage areas.

The first set of modeled fractures (216) and the second set of modeled fractures (218) may be uploaded from the geo-mechanical stress model into the reservoir model (206). In other embodiments, the geo-mechanical stress model may be upscaled into the reservoir model (206) and the first set of modeled fractures (216) and the second set of modeled fractures (218) may be created directly in the reservoir model (206).

In accordance with one or more embodiments, the center location of a fracture may be represented in the reservoir model (206) using the measured depth of the well or the (x, y, z) coordinate system. In accordance with one or more embodiments, the first set of modeled fractures (216) and the second set of modeled fractures (218) may require finer grid cells (224) to be used around the modeled first well (208) and the modeled second well (210) such that the difference between wellbore pressure and cell pressure is insignificant. In further embodiments, the first set of modeled fractures (216) and the second set of modeled fractures (218) are created using local grid refinement (LGR) methods.

In accordance with one or more embodiments, the modeled fractures (216, 218) are created using the geo-mechanical simulation and the modeled fractures (216, 218) may overlap. The geo-mechanical simulation receives as an input: rock properties (such as Young's modulus and Poisson's ratio), petro-physical properties (such as porosity, permeability, and saturations), and fracturing parameters (such as fluid injection rate, proppant concentration, well static/bottom hole pressure, and fracture pressure etc.). The modeled fractures (216, 218) will be in a 3D plane at a given location (either MD or XYZ) along the well. To integrate the modeled fractures (216, 218) with the reservoir model (206), the LGR is used because the base grid in a reservoir model (206) is much larger than the grid in the geo-mechanical simulation that created the modeled fractures (216, 218). In accordance with one or more embodiments, the grid size may be up to 0.1 ft for hydraulic fractures. LGR has the flexibility to do one-level refinement to model the only main fracture or do multiple-level refinement using log-spaced fine grid to model main fracture and SRVs (stimulated reservoir volumes) besides the main fracture.

Back to FIG. 1, in S104, a set of planned overlapping fractures (220) are modeled to create a set of modeled overlapping fractures (222). The set of modeled overlapping fractures (222) includes at least one modeled fracture from the first set of modeled fractures (216) that overlaps with a corresponding modeled fracture in the second set of modeled fractures (218). Herein the term overlapping fractures may encompass fractures between two wells that literally combine with one another to create a single fracture in communication with both wells. The term overlapping fractures may also encompass fractures that are close enough to one another that their drainage areas overlap.

FIGS. 2A-2C show the set of planned overlapping fractures (220) in accordance with one or more embodiments. Specifically, FIGS. 2A-2C show four of the fractures in the first set of planned fractures (212) overlapping with four of the fractures the second set of planned fractures (214).

FIGS. 3A-3C show a portion of the first set of modeled fractures (216) overlapping with a portion of the second set of modeled fractures (218) to create the set of modeled overlapping fractures (222). The set of modeled overlapping fractures (222) are created similarly to how the first set of modeled fractures (216) and the second set of modeled fractures (218) are created in the reservoir model (206).

Specifically, when the first set of modeled fractures (216) and the second set of modeled fractures (218) are created in the reservoir model (206), whichever fractures from the first set of modeled fractures (216) and the second set of modeled fractures (218) that overlap with one another create the set of modeled overlapping fractures (222). Which fractures overlap with one another may be determined by analyzing the drainage areas of each fracture. If the drainage areas substantially overlap with one another, then the fractures may be deemed to overlap.

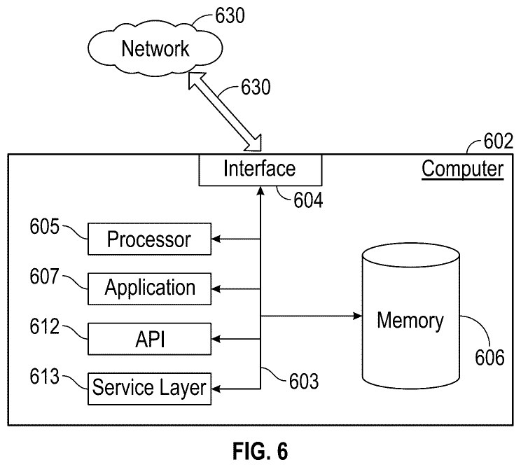

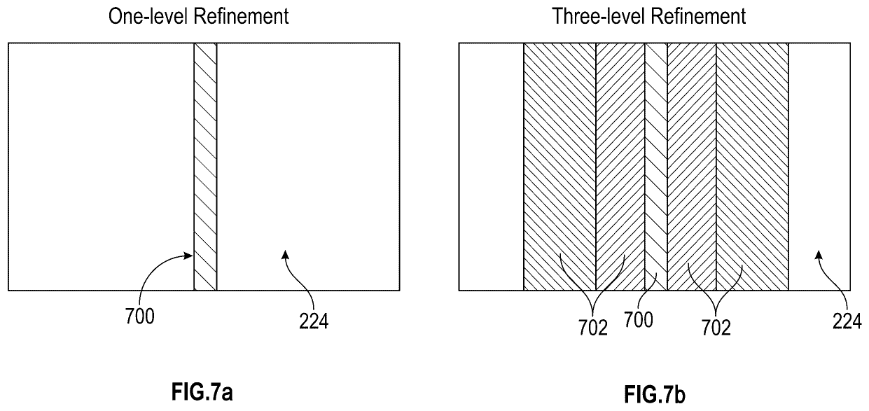

In accordance with one or more embodiments, the grid cells (224) in the reservoir model (206) that make up the set of modeled overlapping fractures (222) undergo Laplacian smoothing and auto-sized fracture levels. FIGS. 7a and 7b show the difference between one level of grid refinement (FIG. 7a) versus three levels of grid refinement (FIG. 7b). Specifically, FIGS. 7a and 7b show a main fracture (700) modeled in a single grid cell (224) of the reservoir model (206). The main fracture (700) may be one of the modeled fractures (216, 218) in accordance with one or more embodiments.

The Laplacian smoothing and auto-sized fracture level ensure the grid cell (224) can fit all the refined grids for the main fracture (700) and the simulated reservoir volumes (702). This is especially beneficial when many fractures (or overlapping fractures) intersect in the same grid cell (224). In this case, if all the fractures cannot be fit into one grid cell (224), the level of refinement will be automatically adjusted to ensure that the main fracture (700) is modeled.

Continuing with FIG. 1, in S106, initial production and production rates of the modeled first well (208) are modeled using the first set of modeled fractures (216) prior to initialization of production on the modeled second well (210). In S108, initial production and production rates of the modeled second well (210) are modeled, using the second set of modeled fractures (218) and the set of modeled overlapping fractures (222), after the modeled first well (208) has been producing for a period of time.

FIGS. 2A and 3A show the wells at time zero. Specifically, FIG. 2A shows the first well (200) and the second well (202) prior to either one being “put on production,” and FIG. 3A shows the modeled first well (208) and the modeled second well (210) prior to either one being “put on production.” In accordance with one or more embodiments, “put on production” means digitally or actually initiating production of the wells. In other words, “put on production” means digitally or actually allowing reservoir fluids, such as hydrocarbons, to flow from the reservoir, through the fractures, and to the surface to be produced. As such, FIG. 2A shows no conductivity within the first set of planned fractures (212) or the second set of planned fractures (214), and FIG. 3A shows no conductivity within the first set of modeled fractures (216) or the second set of modeled fractures (218).

FIG. 2B shows the first well (200) and the second well (202) at time one (T1). Specifically, FIG. 2B shows the first well (200) and the second well (202) after production is initialized on the first well (200). As can be seen in FIG. 2B, the first set of planned fractures (212) is allowing reservoir fluids to flow from the sub-surface reservoir (204) to the first well (200) to be produced, and the second set of planned fractures (214) is still un-conductive and is not providing a pathway for reservoir fluids to flow from the sub-surface reservoir (204) to the second well (202) to be produced.

As such, the fractures that are located in both the first set of planned fractures (212) and the set of planned overlapping fractures (220) have full permeability. Because the second well (202) is not producing, the fractures in the first set of planned fractures (212) that are also part of the set of planned overlapping fractures (220) are able to drain reservoir fluids from their drainage areas with no interference from their corresponding overlapping fractures in the second set of planned fractures (214).

FIG. 3B shows the reservoir model (206) modeling flow at time one (T1). Specifically, FIG. 3B shows the modeled first well (208) and the modeled second well (210) after production is initialized on the modeled first well (208). As can be seen in FIG. 3B, at time one (T1), all production from fractures that are part of both the first set of modeled fractures (216) and the set of modeled overlapping fractures (222) flows to the modeled first well (208).

At time one (T1), a dynamic permeability model is applied to the reservoir model (206) in order to capture permeability changes in the set of modeled overlapping fractures (222) over time. In accordance with one or more embodiments, the dynamic permeability model is configured to update the permeability in an area of interest over time by specifying the grid cells (224) around a particular fracture or a region of interest (e.g., distance from a given fracture).

FIG. 2C shows the first well (200) and the second well (202) at time two (T2). Specifically, FIG. 2C shows the first well (200) and the second well (202) after production is initialized on the second well (202). In accordance with one or more embodiments, production is initialized on the second well (202) after the first well (200) has been producing for a period of time. The period of time has no bounds.

When production is initialized on the second well (202), the first set of planned fractures (212) is still allowing reservoir fluids to flow from the sub-surface reservoir (204) to the first well (200) to be produced, and second set of planned fractures (214) begins to allow reservoir fluids to flow from the sub-surface reservoir (204) to the second well (202) to be produced.

As can be seen in FIG. 2C, the initialization of production on the second well (202) at time two (T2) causes the permeability to decrease in the set of planned overlapping fractures (220) compared to the permeability of the conducting fractures at time one (T1). Permeability decreases in the set of planned overlapping fractures (220) at time two (T2) because there are now at least two fractures producing from the same drainage area, whereas, at time one (T1), there is only one fracture producing from said drainage area.

FIG. 3C shows the reservoir model (206) modeling flow at time two (T2). Specifically, FIG. 3C shows the modeled first well (208) and the modeled second well (210) after production is initialized on the modeled second well (210). At time two (T2), the production from the set of modeled overlapping fractures (222) is split and is flowing to both the modeled first well (208) and the modeled second well (210). Due to the application of the dynamic permeability model to the reservoir model (206), the reservoir model (206) is able to represent this change in permeability.

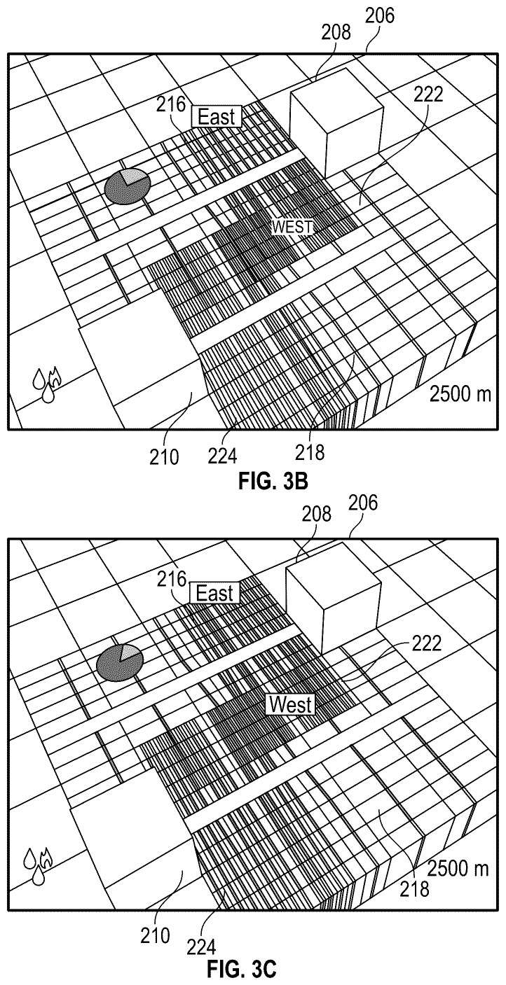

In S110, an effect (226) on the production rates of the modeled first well (208) is analyzed. The effect is any change in production rates of the modeled wells. The effect (226) is due to the set of modeled overlapping fractures (222) and the initial production on the modeled second well (210). FIG. 4 shows the effect (226) in accordance with one or more embodiments. Specifically, FIG. 4 shows a plot of production rate over time. An adjusted production rate (228) and an unadjusted production rate (230) are shown graphed on the plot.

The unadjusted production rate (230) represents the production rates of the modeled first well (208) when the set of modeled overlapping fractures (222) have not been taken into account. The adjusted production rate (228) represents the production rates of the modeled first well (208) taking into account the set of modeled overlapping fractures (222). In particular, the unadjusted production rate (230) treats the fractures in the set of modeled overlapping fractures (222) as if they do not overlap with one another.

The effect (226) of the set of modeled overlapping fractures (222) is represented on the graph and is equal to the difference between the adjusted production rate (228) and the unadjusted production rate (230). In accordance with one or more embodiments, the unadjusted production rate (230) is equal to the modeled production rates of the modeled first well (208) at time one (T1), and the unadjusted production rate (230) is equal to the modeled production rates of the modeled first well (208) from time two (T2). As such, the effect (226) may be equal to the change in production rates of the modeled first well (208) from time one (T1) and the change is based on the communication between the set of modeled overlapping fractures (222).

In S112, the effect (226) on the production rates of the modeled first well (208) are minimized by updating locations of the first set of modeled fractures (216) and the second set of modeled fractures (218) to optimize the set of modeled overlapping fractures (222). In accordance with one or more embodiments, the effect (226) may be minimized by picking the location of the first set of modeled fractures (216) in the modeled first well (208) and the location of the second set of modeled fractures (218) in the modeled second well (210) to minimize communication between the set of modeled overlapping fractures (222) at time two (T2).

Changing locations may include changing the perforation scheme of the first well (200) and the second well (202) to optimize the drainage areas of the first set of modeled fractures and the second set of modeled fractures. Optimizing the drainage areas may include reducing the amount drainage area that is shared between two overlapping fractures. In further embodiments, changing locations may include changing the planned wellbore trajectories of the first well (200) and the second well (202). The changed locations may be updated in the reservoir model (206) and S100-S110 of the method may be repeated until production of both the first well (200) and the second well (202) has been sufficiently optimized.

In S114, a signal (544) having the updated locations of the first set of modeled fractures (216) and the second set of modeled fractures (218) is sent to a fracturing system and the first well (200) and the second well (202) are fractured using the fracturing system based on the updated locations. In accordance with one or more embodiments, the signal (544) may be sent automatically to the fracturing system to change the perforation scheme of the first well (200) or the second well (202). The fracturing system may be any type of fracturing system known in the art, such as a hydraulic fracturing site (500).

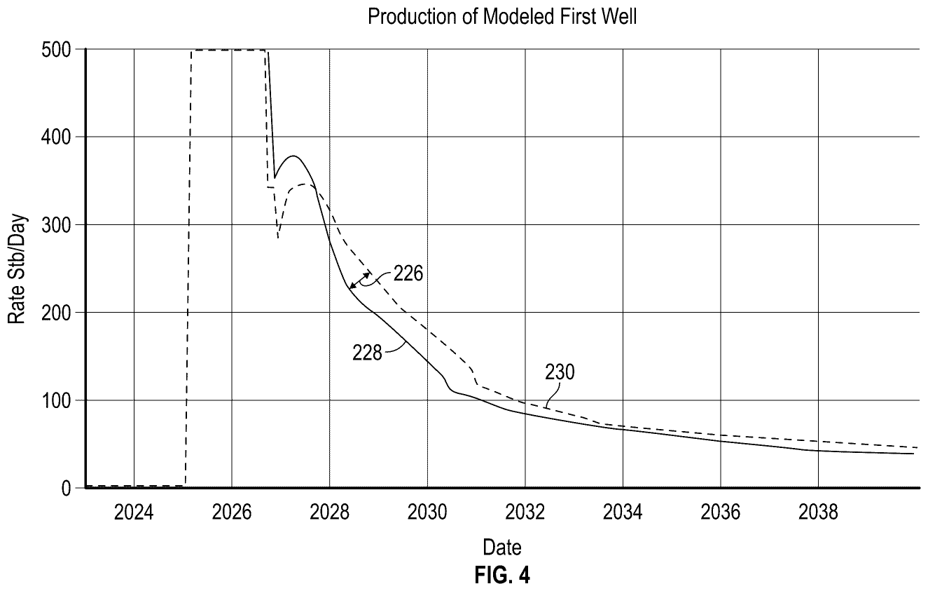

FIG. 5 shows a hydraulic fracturing site (500) undergoing a hydraulic fracturing operation in accordance with one or more embodiments. The particular hydraulic fracturing operation and hydraulic fracturing site (500) shown is for illustration purposes only. The scope of this disclosure is intended to encompass any type of fracturing site and fracturing operation. In general, a hydraulic fracturing operation includes two separate operations: a perforation operation and a pumping operation.

In further embodiments, a hydraulic fracturing operation is performed in stages and on multiple wells that are geographically grouped. A singular well may have anywhere from one to more than forty stages. Typically, each stage includes one perforation operation and one pumping operation. While one operation is occurring on one well, a second operation may be performed on the other well. As such, FIG. 5 shows a hydraulic fracturing operation occurring on the first well (200) and the second well (202). The first well (200) is undergoing the perforation operation and the second well (202) is undergoing the pumping operation. The hydraulic fracturing operation is being performed to execute the first set of modeled fractures (216) and the second set of modeled fractures (218) based on the updated locations determined above in S112.

The first well (200) and the second well (202) are horizontal wells meaning that each well includes a vertical section and a lateral section. The lateral section is a section of the well that is drilled at least eighty degrees from vertical. The first well (200) is capped by a first frac tree (506) and the second well (202) is capped by a second frac tree (508). A frac tree (506, 508) is similar to a Christmas/production tree but is specifically installed for the hydraulic fracturing operation. Frac trees (506, 508) tend to have larger bores and higher-pressure ratings than a Christmas/production tree would have. Further, hydraulic fracturing operations require abrasive materials being pumped into the well at high pressures, so the frac tree (506, 508) is designed to handle a higher rate of erosion.

In accordance with one or more embodiments, the first well (200) and the second well (202) each require four stages. Both the first well (200) and the second well (202) have undergone three stages and are undergoing the fourth stage. The second well (202) has already undergone the fourth stage perforation operation and is currently undergoing the fourth stage pumping operation. The first well (200) is undergoing the fourth stage perforating operation and has yet to undergo the fourth stage pumping operation.

In accordance with one or more embodiments, the perforating operation includes installing a wireline blow out preventor (BOP) (510) onto the first frac tree (506). A wireline BOP (510) is similar to a drilling BOP; however, a wireline BOP (110) has seals designed to close around (or shear) wireline (512) rather than drill pipe. A lubricator (514) is connected to the opposite end of the wireline BOP (510). A lubricator (514) is a long, high-pressure pipe used to equalize downhole pressure and atmosphere pressure in order to run downhole tools, such as a perforating gun (516), into the well.

The perforating gun (516) is pumped into the first well (200) using the lubricator (514), wireline (512), and fluid pressure. In accordance with one or more embodiments, the perforating gun (516) is equipped with explosives and a frac plug (518) prior to being deployed in the first well (200). The wireline (512) is connected to a spool (520) often located on a wireline truck (522). Electronics (not pictured) included in the wireline truck (522) are used to control the unspooling/spooling of the wireline (512) and are used to send and receive messages along the wireline (512). The electronics may also be connected, wired or wirelessly, to a monitoring system (524) that is used to monitor and control the various operations being performed on the hydraulic fracturing site (500).

When the perforating gun (516) reaches a predetermined depth, a message is sent along the wireline (512) to set the frac plug (518). After the frac plug (518) is set, another message is sent through the wireline (512) to detonate the explosives, as shown in FIG. 5. The explosives create perforations in the casing (526) and in the surrounding formation. There may be more than one set of explosives on a singular perforation gun (516), each detonated by a distinct message. Multiple sets of explosives are used to perforate different depths along the casing (526) for a singular stage. Further, the frac plug (518) may be set separately from the perforation operation without departing from the scope of the disclosure herein.

In accordance with one or more embodiments, the hydraulic fracturing site (100) includes a computer (602) coupled to the site (100). In particular, the computer (602) may be coupled to a computer in the wireline truck (522) or elsewhere on the hydraulic fracturing site (100), such as in the site manager's office. A signal (544) may be sent from the computer (602) to the hydraulic fracturing site (100). The signal (544) may include the updated locations of the first set of modeled fractures (216) and the second set of modeled fractures (218). The personnel on location may use the updated locations of the first set of modeled fractures (216) and the second set of modeled fractures (218) to modify the perforation operation.

As explained above, FIG. 5 shows the second well (202) undergoing the pumping operation after the fourth stage perforating operation has already been performed and perforations are left behind in the casing (526) and the surrounding formation. A pumping operation includes pumping a frac fluid (528) into the perforations in order to propagate the perforations and create fractures (542) in the surrounding formation. The fractures (542) shown in FIG. 5 may be the physical embodiments of the first set of planned fractures (212), the second set of planned fractures (214), the first set of modeled fractures (216), or the second set of modeled fractures (218).

The frac fluid (528) often comprises a certain percentage of water, proppant, and chemicals. FIG. 5 shows chemical storage containers (530), water storage containers (532), and proppant storage containers (534) located on the hydraulic fracturing site (500). Frac lines (536) and transport belts (not pictured) transport the chemicals, proppant, and water from the storage containers (530, 532, 534) into a frac blender (538). A plurality of sensors (not pictured) are located throughout this equipment to send signals to the monitoring system (524). The monitoring system (524) may be used to control the volume of water, chemicals, and proppant used in the pumping operation.

The frac blender (538) blends the water, chemicals, and proppant to become the frac fluid (528). The frac fluid (528) is transported to one or more frac pumps, often pump trucks (540), to be pumped through the second frac tree (508) into the second well (202). Each pump truck (540) includes a pump designed to pump the frac fluid (528) at a certain pressure. More than one pump truck (540) may be used at a time to increase the pressure of the frac fluid (528) being pumped into the second well (202). The frac fluid (528) is transported from the pump truck (540) to the second frac tree (508) using a plurality of frac lines (536).

The fluid pressure propagates and creates the fractures (542) while the proppant props open the fractures (542) once the pressure is released. Different chemicals may be used to lower friction pressure, prevent corrosion, etc. The pumping operation may be designed to last a certain length of time to ensure the fractures (542) have propagated enough. Further the frac fluid (528) may have different make ups throughout the pumping operation to optimize the pumping operation without departing from the scope of the disclosure herein.

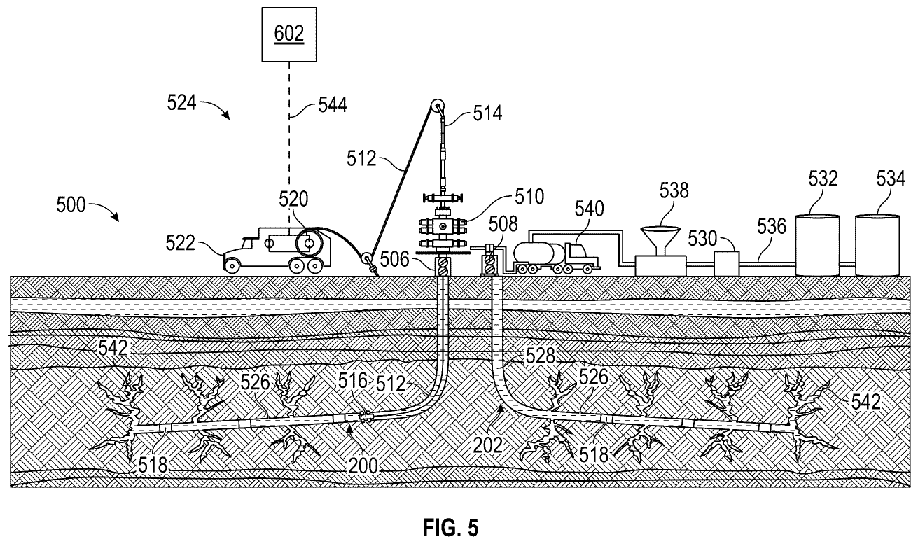

FIG. 6 shows a computer (602) system in accordance with one or more embodiments. Specifically, FIG. 6 shows a block diagram of a computer (602) system used to provide computational functionalities associated with described algorithms, methods, functions, processes, flows, and procedures as described in the instant disclosure, according to an implementation. The illustrated computer (602) is intended to encompass any computing device such as a server, desktop computer, laptop/notebook computer, wireless data port, smart phone, personal data assistant (PDA), tablet computing device, one or more processors within these devices, or any other suitable processing device, including both physical or virtual instances (or both) of the computing device.

Additionally, the computer (602) may include a computer that includes an input device, such as a keypad, keyboard, touch screen, or other device that can accept user information, and an output device that conveys information associated with the operation of the computer (602), including digital data, visual, or audio information (or a combination of information), or a GUI.

The computer (602) can serve in a role as a client, network component, a server, a database or other persistency, or any other component (or a combination of roles) of a computer system for performing the subject matter described in the instant disclosure. The illustrated computer (602) is communicably coupled with a network (630). In some implementations, one or more components of the computer (602) may be configured to operate within environments, including cloud-computing-based, local, global, or other environment (or a combination of environments).

At a high level, the computer (602) is an electronic computing device operable to receive, transmit, process, store, or manage data and information associated with the described subject matter. According to some implementations, the computer (602) may also include or be communicably coupled with an application server, e-mail server, web server, caching server, streaming data server, business intelligence (BI) server, or other server (or a combination of servers).

The computer (602) can receive requests over network (630) from a client application (for example, executing on another computer (602)) and responding to the received requests by processing the said requests in an appropriate software application. In addition, requests may also be sent to the computer (602) from internal users (for example, from a command console or by other appropriate access method), external or third-parties, other automated applications, as well as any other appropriate entities, individuals, systems, or computers.

Each of the components of the computer (602) can communicate using a system bus (603). In some implementations, any or all of the components of the computer (602), both hardware or software (or a combination of hardware and software), may interface with each other or the interface (604) (or a combination of both) over the system bus (603) using an application programming interface (API) (612) or a service layer (613) (or a combination of the API (612) and service layer (613). The API (612) may include specifications for routines, data structures, and object classes. The API (612) may be either computer-language independent or dependent and refer to a complete interface, a single function, or even a set of APIs. The service layer (613) provides software services to the computer (602) or other components (whether or not illustrated) that are communicably coupled to the computer (602).

The functionality of the computer (602) may be accessible for all service consumers using this service layer. Software services, such as those provided by the service layer (613), provide reusable, defined business functionalities through a defined interface. For example, the interface may be software written in JAVA, C++, or other suitable language providing data in extensible markup language (XML) format or other suitable format. While illustrated as an integrated component of the computer (602), alternative implementations may illustrate the API (612) or the service layer (613) as stand-alone components in relation to other components of the computer (602) or other components (whether or not illustrated) that are communicably coupled to the computer (602). Moreover, any or all parts of the API (612) or the service layer (613) may be implemented as child or sub-modules of another software module, enterprise application, or hardware module without departing from the scope of this disclosure.

The computer (602) includes an interface (604). Although illustrated as a single interface (604) in FIG. 6, two or more interfaces (604) may be used according to particular needs, desires, or particular implementations of the computer (602). The interface (604) is used by the computer (602) for communicating with other systems in a distributed environment that are connected to the network (630). Generally, the interface (604) includes logic encoded in software or hardware (or a combination of software and hardware) and operable to communicate with the network (630). More specifically, the interface (604) may include software supporting one or more communication protocols associated with communications such that the network (630) or interface's hardware is operable to communicate physical signals within and outside of the illustrated computer (602).

The computer (602) includes at least one computer processor (605). Although illustrated as a single computer processor (605) in FIG. 6, two or more processors may be used according to particular needs, desires, or particular implementations of the computer (602). Generally, the computer processor (605) executes instructions and manipulates data to perform the operations of the computer (602) and any algorithms, methods, functions, processes, flows, and procedures as described in the instant disclosure.

The computer (602) also includes a non-transitory computer (602) readable medium, or a memory (606), that holds data for the computer (602) or other components (or a combination of both) that can be connected to the network (630). For example, memory (606) can be a database storing data consistent with this disclosure. Although illustrated as a single memory (606) in FIG. 6, two or more memories may be used according to particular needs, desires, or particular implementations of the computer (602) and the described functionality. While memory (606) is illustrated as an integral component of the computer (602), in alternative implementations, memory (606) can be external to the computer (602).

The application (607) is an algorithmic software engine providing functionality according to particular needs, desires, or particular implementations of the computer (602), particularly with respect to functionality described in this disclosure. For example, application (607) can serve as one or more components, modules, applications, etc. Further, although illustrated as a single application (607), the application (607) may be implemented as multiple applications (607) on the computer (602). In addition, although illustrated as integral to the computer (602), in alternative implementations, the application (607) can be external to the computer (602).

There may be any number of computers (602) associated with, or external to, a computer system containing computer (602), each computer (602) communicating over network (630). Further, the term “client,” “user,” and other appropriate terminology may be used interchangeably as appropriate without departing from the scope of this disclosure. Moreover, this disclosure contemplates that many users may use one computer (602), or that one user may use multiple computers (602).

Although only a few example embodiments have been described in detail above, those skilled in the art will readily appreciate that many modifications are possible in the example embodiments without materially departing from this invention. Accordingly, all such modifications are intended to be included within the scope of this disclosure as defined in the following claims.

What is claimed:

1. A method for fracturing a first well and a second well in a sub-surface reservoir, the method comprising:
modeling the first well and the second well in a reservoir model representing the sub-surface reservoir to create a modeled first well and a modeled second well;
modeling a first set of planned fractures extending from the first well and a second set of planned fractures extending from the second well in the reservoir model to create a first set of modeled fractures and a second set of modeled fractures;
modeling a set of planned overlapping fractures to create a set of modeled overlapping fractures, wherein the set of modeled overlapping fractures includes at least one modeled fracture from the first set of modeled fractures that overlaps with a corresponding modeled fracture in the second set of modeled fractures;
modeling initial production and production rates of the modeled first well using the first set of modeled fractures prior to initialization of production on the modeled second well;
modeling initial production and production rates of the modeled second well, using the second set of modeled fractures and the set of modeled overlapping fractures, after the modeled first well has been producing for a period of time;
analyzing an effect on the production rates of the modeled first well, wherein the effect is a change in production rates due to the set of modeled overlapping fractures and the initial production on the modeled second well; and
minimizing the effect on the production rates of the modeled first well by updating locations of the first set of modeled fractures and the second set of modeled fractures to optimize the set of modeled overlapping fractures.

2. The method of claim 1, further comprising sending a signal having the updated locations of the first set of modeled fractures and the second set of modeled fractures to a fracturing system and fracturing the first well and the second well using the fracturing system based on the updated locations.

3. The method of claim 1, further comprising creating the reservoir model by upscaling a geological model representing geological properties of the sub-surface reservoir and incorporating data from a fluid model and a relative permeability model, and wherein modeling the first set of planned fractures and the second set of planned fractures in the reservoir model further comprises simulating the first set of planned fractures and the second set of planned fractures using a geo-mechanical stress model, a wellbore trajectory of the first well and the second well, and a planned perforation scheme of the first well and the second well.

4. The method of claim 1, wherein modeling the first set of planned fractures and the second set of planned fractures in the reservoir model further comprises using local grid refinement methods to create the first set of modeled fractures and the second set of modeled fractures and their corresponding stimulated reservoir volumes.

5. The method of claim 1, wherein modeling the set of planned overlapping fractures to create the set of modeled overlapping fractures further comprises applying Laplacian smoothing and auto-sized fracture levels.

6. The method of claim 1, wherein modeling the initial production and the production rates of the modeled first well and the modeled second well comprises modeling initial production of the modeled first well at time one, wherein time one includes all production from fractures that are part of both the first set of modeled fractures and the set of modeled overlapping fractures flowing to the modeled first well after production is initialized on the modeled first well.

7. The method of claim 6, wherein modeling the production rates of the modeled first well and the modeled second well comprises modeling the production rates at time two, wherein time two includes the production from the set of overlapping fractures being split and flowing to both the modeled first well and the modeled second well when production is initialized on the modeled second well.

8. The method of claim 6, wherein modeling production rates at time one further comprises updating a permeability of the set of modeled overlapping fractures using a dynamic permeability model.

9. The method of claim 7, wherein analyzing the effect on the production rates of the modeled first well further comprises determining a change in production rates of the modeled first well from time one based on communication between the set of modeled overlapping fractures.

10. The method of claim 9, wherein minimizing the effect on the production rates of the modeled first well further comprises picking the location of the first set of modeled fractures in the modeled first well and the location of the second set of modeled fractures in the modeled second well to minimize communication between the set of modeled overlapping fractures at time two.

11. A system for fracturing a first well and a second well in a sub-surface reservoir, the system comprising:
a fracturing system comprising a pump truck configured to pump a frac fluid into the first well to create a first set of fractures extending from the first well into the sub-surface reservoir and pump the frac fluid into the second well to create a second set of fractures extending from the second well into the sub-surface reservoir; and
a computer system coupled to the fracturing system and configured to perform functionalities related to:
modeling the first well and the second well in a reservoir model representing the sub-surface reservoir to create a modeled first well and a modeled second well;
modeling a first set of planned fractures extending from the first well and a second set of planned fractures extending from the second well in the reservoir model to create a first set of modeled fractures and a second set of modeled fractures;
modeling a set of planned overlapping fractures to create a set of modeled overlapping fractures, wherein the set of modeled overlapping fractures includes at least one modeled fracture from the first set of modeled fractures that overlaps with a corresponding modeled fracture in the second set of modeled fractures;
modeling initial production and production rates of the modeled first well using the first set of modeled fractures prior to initialization of production on the modeled second well;
modeling initial production and production rates of the modeled second well, using the second set of modeled fractures and the set of modeled overlapping fractures, after the modeled first well has been producing for a period of time;
analyzing an effect on the production rates of the modeled first well, wherein the effect is a change in production rates due to the set of modeled overlapping fractures and the initial production on the modeled second well; and
minimizing the effect on the production rates of the modeled first well by updating locations of the first set of modeled fractures and the second set of modeled fractures to optimize the set of modeled overlapping fractures.

12. The system of claim 11, wherein the computer system has further functionalities related to sending a signal having the updated locations of the first set of modeled fractures and the second set of modeled fractures to the fracturing system and fracture the first well and the second well to create the first set of fractures and the second set of fractures based on the updated locations.

13. The system of claim 11, wherein the computer system has further functionalities related to creating the reservoir model by upscaling a geological model representing geological properties of the sub-surface reservoir and incorporating data from a fluid model and a relative permeability model, and wherein modeling the first set of planned fractures and the second set of planned fractures in the reservoir model further comprises simulating the first set of planned fractures and the second set of planned fractures using a geo-mechanical stress model, a wellbore trajectory of the first well and the second well, and a planned perforation scheme of the first well and the second well.

14. The system of claim 11, wherein modeling the first set of planned fractures and the second set of planned fractures in the reservoir model further comprises using local grid refinement methods to create the first set of modeled fractures and the second set of modeled fractures and their corresponding stimulated reservoir volumes.

15. The system of claim 11, wherein modeling the set of planned overlapping fractures to create the set of modeled overlapping fractures further comprises applying Laplacian smoothing and auto-sized fracture levels.

16. The system of claim 11, wherein modeling the initial production and the production rates of the modeled first well and the modeled second well comprises modeling initial production of the modeled first well at time one, wherein time one includes all production from fractures that are part of both the first set of modeled fractures and the set of modeled overlapping fractures flowing to the modeled first well after production is initialized on the modeled first well.

17. The system of claim 16, wherein modeling the production rates of the modeled first well and the modeled second well comprises modeling the production rates at time two, wherein time two includes the production from the set of overlapping fractures being split and flowing to both the modeled first well and the modeled second well when production is initialized on the modeled second well.

18. The system of claim 16, wherein modeling production rates at time one further comprises updating a permeability of the set of modeled overlapping fractures using a dynamic permeability model.

19. The system of claim 17, wherein analyzing the effect on the production rates of the modeled first well further comprises determining a change in production rates of the modeled first well from time one based on communication between the set of modeled overlapping fractures.

20. The system of claim 19, wherein minimizing the effect on the production rates of the modeled first well further comprises picking the location of the first set of modeled fractures in the modeled first well and the location of the second set of modeled fractures in the modeled second well to minimize communication between the set of modeled overlapping fractures at time two.
